(19) United States
(12) Patent Application Publication
(10) Pub. No.: US 2026/0190365 A1
(43) Pub. Date: Jul. 2, 2026

(54) TRANSISTOR WITH 2D CHANNEL MATERIAL CLADDING GATE STACKS

(71) Applicant: Intel Corporation, Santa Clara, CA (US)

(72) Inventors: Chia-Ching Lin, Portland, OR (US); Carl H. Naylor, Portland, OR (US); Uygar Avci, Portland, OR (US); Kevin P. O'Brien, Portland, OR (US); Mahmut Sami Kavrik, Hillsboro, OR (US); Arnab Sen Gupta, Hillsboro, OR (US); Kirby Maxey, Hillsboro, OR (US); Tao Chu, Portland, OR (US); Guowei Xu, Portland, OR (US); Robin Chao, Portland, OR (US); Feng Zhang, Portland, OR (US); Yang Zhang, Rio Rancho, NM (US); Ting-Hsiang Hung, Beaverton, OR (US); Chun Wing Yeung, Portland, OR (US); Chelsey Dorow, Portland, OR (US); Wouter Mortelmans, Portland, OR (US); Kan Zhang, Hillsboro, OR (US)

(73) Assignee: Intel Corporation, Santa Clara, CA (US)

(21) Appl. No.: 19/002,544

(22) Filed: Dec. 26, 2024

(51) Int. Cl. H10D 30/01; H10D 30/47; H10D 30/67; H10D 62/10; H10D 84/03; H10D 84/83

(52) U.S. Cl. CPC H10D 30/017; H10D 30/481; H10D 30/6735; H10D 30/6757; H10D 62/121; H10D 84/038; H10D 84/83

(57) ABSTRACT

In a transistor structure, a 2D channel material is formed after fabrication of a gate insulator and gate (electrode). In accordance with some exemplary “channel-material last” embodiments, a contact area between the 2D channel material and a source terminal and/or drain terminal is much larger than an edge or layer thickness of the 2D channel material, which may only be a few nanometers, for example. This larger contact area may significantly reduce external resistance of a transistor structure. Doping and strain engineering may also be more successfully applied to the “channel-material last” transistor structures disclosed herein, further boosting transistor performance.

### BACKGROUND

For advanced integrated circuits, the performance of silicon-based transistors drops significantly at reduced gate lengths, even for gate-all-around (GAA) or nanoribbon or wire (RoW) transistors. In silicon-based devices, a reduced thickness of the silicon semiconductor material has a detrimental impact on the charge carrier mobility. This issue has motivated development of non-silicon materials.

One class of non-silicon materials is a compound of one or more metals and one or more chalcogens. Transition metal dichalcogenides (TMD or TMDC) are one exemplary species of the metal chalcogen class of materials. TMDCs display semiconductor properties as a unit cell of MX₂, where M is a transition metal atom (e.g., Mo, W) and X is a chalcogen atom (S, Se, or Te). Metal chalcogenide materials have been of significant interest in highly-scaled integrated circuitry. One advantage is the thin (two-dimensional) active layers with high mobility possible even when very thin (e.g., about 1-2 nm) and so are often referred to generically as 2D materials. Other 2D materials are also known, with graphene being another example.

However, deployment of 2D channel materials in transistor structures poses many challenges. For example, such thin layers may not survive the large number of operations typically performed in advanced transistor fabrication.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a transistor structure having a 2D channel material cladding a gate stack structure, in accordance with some “channel material last” embodiments;

FIGS. 2, 3, 4, 5, 6, 7, 8, 9, 10 and 11A are cross-sectional views of transistor structures evolving as the methods illustrated in FIG. 1 are practiced, in accordance with some embodiments;

FIGS. 11B and 11C are cross-sectional views of the transistor structure illustrated in FIG. 11A along an orthogonal dimension, in accordance with some embodiments;

FIG. 12 is a cross-sectional view of a monolithic IC structure comprising a transistor structure having 2D channel material cladding a gate stack, in accordance with some embodiments;

FIG. 13 illustrates a mobile computing platform and a data server machine employing an IC device including transistor structures having 2D channel material cladding a gate stack, in accordance with some embodiments; and

FIG. 14 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

In accordance with embodiments herein, a transistor structure includes a 2D channel material. In some embodiments, the 2D material is a metal chalcogen. A 2D metal chalcogenide material, or another 2D material, such as graphene, etc. may be advantageously implemented as channel material in a transistor structure where the channel material is vertically stacked. However, 2D channel material may be unable to survive a great number of transistor fabrication processes, such as formation of a high-k gate insulator and/or gate material adjacent to the 2D channel material, etc. Accordingly, embodiments herein implement a “channel-material last” fabrication strategy.

As used herein, a 2D channel material is adjacent to a gate insulator and gate (electrode) and that is electrically coupled to the gate through the gate insulator during operation of a transistor structure. Accordingly, “2D channel material” is a structural term specifying a physical region or body within a three-terminal transistor structure. As further used herein, a channel material is a material in the channel region of a transistor structure.

In exemplary “channel-material last” embodiments, a 2D channel material is deposited, grown, or otherwise formed after fabricating a gate insulator and gate (electrode) structure. As further described below, in accordance with some exemplary “channel-material last” embodiments, cladding a gate structure with the 2D channel material enables the contact area between the 2D channel material and a source terminal and/or drain terminal to be much larger than an edge or layer thickness of the 2D channel material. This larger contact area may significantly reduce external resistance associated with a transistor structure. Doping and strain engineering may also be more successfully applied to the “channel-material last” transistor structures disclosed herein, further boosting transistor performance.

In some exemplary embodiments, the 2D channel material layer extends a length between source and drain terminals of the transistor and has opposite ends of a large surface area that directly contact source and drain contact metallization. The 2D material layer may line each of a stack of (nano) tunnels or (nano) tubes that extend through a length of a gate stack. Individual ones of the tunnels/tubes may be contain a dielectric material that also extends between source and drain terminals of the transistor.

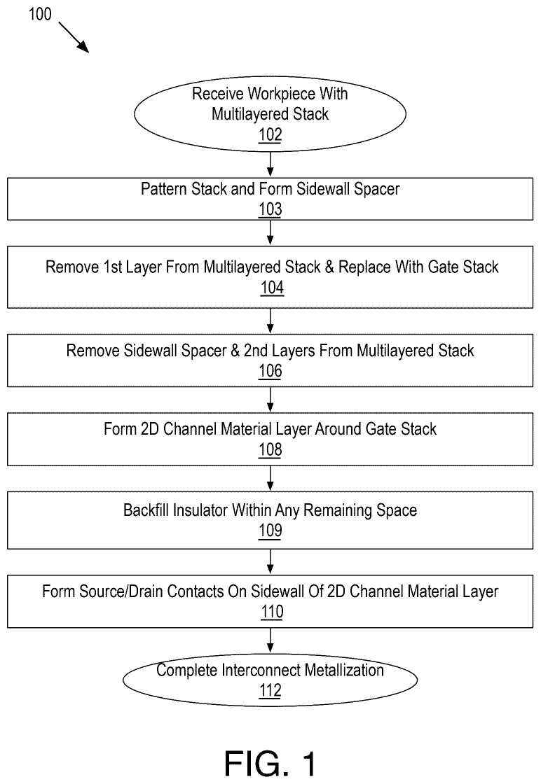

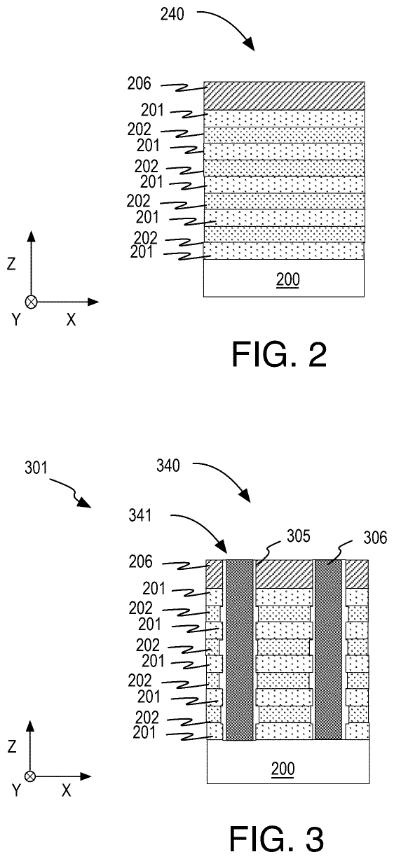

FIG. 1 is a flow diagram illustrating methods 100 for forming a transistor structure having a 2D channel material cladding a gate stack, in accordance with some “channel material last” embodiments. Methods 100 may be practiced as a wafer-level device fabrication process, for example. FIGS. 2-11C are cross-sectional views of transistor structures evolving as the methods 100 are practiced in accordance with some exemplary embodiments. Methods other than methods 100 may be practiced to arrive at structures similar, if not identical to, those illustrated in FIG. 2-11C. Likewise, methods 100 may be practiced to arrive at structures other than those illustrated in FIG. 2-11C.

Methods 100 begin at input 102, where a workpiece is received for processing. In some examples, the substrate received at input 102 comprise a 300-450 mm diameter wafer. The substrate may include a substantially monocrystalline material, for example. Over the monocrystalline material there is a multiple material layer stack comprising one or more material bilayers. Each bilayer comprises a first material layer interleaved with a second material layer. In some exemplary embodiments, neither of the first or second material layers are to become retained in a transistor structure. Instead, both the first and second material layers may be considered sacrificial and are to function as mandrel layers around which permanent transistor structures, such as a gate stack and channel semiconductor, are fabricated. Optionally, the multi-layer stack received at input 102 may further include one or more hard mask layers and/or one or more etch stop layers.

Various layers of the multilayer stack received at input 102 may be formed by practicing in succession any thin film deposition technique(s) suitable for each material layer composition, such as one or more of atomic layer deposition (ALD), chemical vapor deposition (CVD), plasma enhanced chemical vapor deposition (PECVD), metal-organic chemical vapor deposition (MOCVD), or molecular beam deposition/epitaxy (MBE).

FIG. 2 illustrates a cross-sectional side view of an exemplary multilayer stack 240 over a substrate 200. In some exemplary embodiments, substrate 200 includes a crystalline material comprising one or more Group IV elements. For example, substrate 200 may comprise a single crystal of any of Si, Ge, SiGe, or GeSn. In other embodiments, the substrate material may comprise one or more (mono) crystalline Group III-V materials (e.g., GaAs), one or more (mono) crystalline Group III-N materials (e.g., GaN). Substrate 200 may further include one or more thin film material layers (not depicted). For example, substrate 200 may include underlying device layer(s) and/or metallization interconnect layers interconnect devices such as transistors, memories, capacitors, resistors, optoelectronic devices, switches, or any other active or passive electronic devices fabricated within the device layer(s).

Multilayer stack 240 includes a plurality of bilayers where a bilayer comprises a first material layer 201 and a second material layer 202. A multilayer material stack may include any number of first material layers 201 interleaved with any number of second material layers 202. In the illustrated example, five material layers 201 are interleaved with four intervening material layers 201. Material layers 202 may have any chemical composition that allows for such material layers to be etched or otherwise removed selectively relative to material layers 201. Material layers 201 may further have any chemical composition that allows for such material layers to be etched or otherwise removed selectively relative to a gate stack that is subsequently formed. In some examples, material layers 201 all have substantially the same composition and material layers 202 all have substantially the same composition.

In some advantageous embodiments, material layers 201 and 202 are all substantially monocrystalline, for example as epitaxially grown upon substrate 200. In further embodiments, both material layers 201 and 202 comprise silicon with a first of material layers 201 and 202 having a higher germanium content than a second of material layers 201 and 202 sufficient to provide adequate etch selectivity. As one example, material layers 201 may be substantially pure silicon while material layers 202 are a SiGe alloy. In another example, material layers 202 may be substantially pure silicon while material layers 201 are a SiGe alloy.

Multilayer stack 240 further includes a hardmask material layer 206, which may have any chemical composition but is advantageously of a composition resistant to etch processes and potentially distinct from material layers 201 and 202. In some examples, hardmask material layer 206 may be primary silicon and carbon (e.g., silicon carbide), silica, or silicon nitride.

Returning to FIG. 1, methods 100 continue at block 103, where the multilayer stack received at input 102 is patterned, for example into a fin structure. A sidewall spacer dielectric material is then formed around the patterned feature comprising the multilayer stack. The multilayer stack may be patterned using any suitable technique or techniques such as lithography and anisotropic etch techniques. The sidewall spacer dielectric material may also be formed using any technique or techniques known to be suitable, such as ALD or CVD.

FIG. 3 illustrates a cross-sectional side view of a structure 301 derived from multilayer stack 240 (FIG. 2). As shown in FIG. 3, opposite ends of a fin 340 are defined by trenches 341 that were etched through multilayer stack 240. Although dimensions may vary with implementation, in some exemplary embodiments fin length (x-dimension) ranges from 10-100 nm while fin width (y-dimension) may range from 4-10 nm.

In the illustrated example, material layers 202 have been recess etched after the formation of trenches 341. The recess etch may be with a wet etch chemistry or plasma-based atomic layer etch (ALE) techniques, for example. The magnitude of the recess etch may vary with implementation. In some examples, the recess is in the range of 1-5 nm and advantageously less than 3 nm. The recess etch, selective to material layers 202, recesses a sidewall of material layers 202 relative to material layers 201, forming dimples. As further illustrated in FIG. 3, a spacer dielectric material 305 has been deposited on a sidewall of fin 340. For embodiments that receive a dimple etch, spacer dielectric material 305 may be thicker within a dimple than outside of the dimple. In some examples, spacer dielectric material 305 is a silicon-based inorganic dielectric (e.g., silica, silicon nitride, silicon carbide, SON, SONC, etc.). Following spacer formation, a filler material 306, which may be another inorganic dielectric or a polymer dielectric, is deposited to substantially fill trenches 341.

Returning to FIG. 1, methods 100 continue at block 104 where first material layers are removed from the material stack and replaced with a gate stack. For example, block 104 may comprise any “gate replacement” process known to be suitable for stacked FET structures. Generally, gate replacement entails etching the first material layers selectively from the second material layers, followed by deposition of a gate insulator around the released second material layers, which is further followed by deposition of gate electrode material. The gate stack is thereby formed within the opening or void formed by the removal of the first material layers. In some examples, the gate insulator is first formed with conformal deposition process, such as ALD. Subsequently, a gate material may be formed over the gate insulator using metal deposition techniques including ALD, a plating technique, or the like.

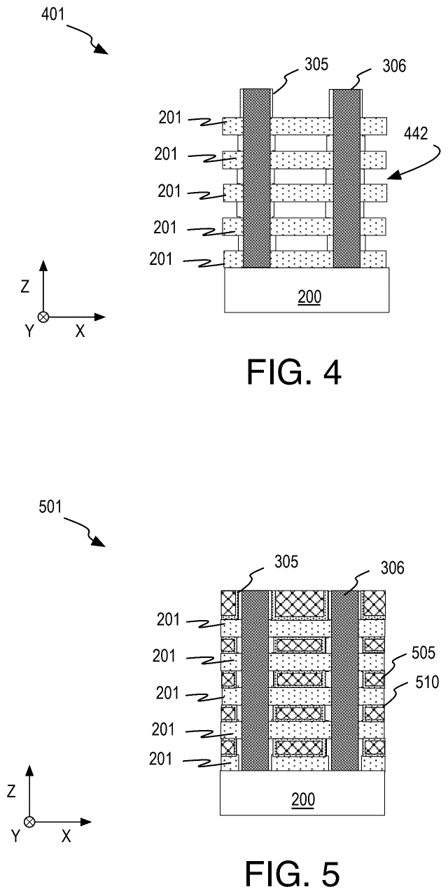

FIG. 4 illustrates a structure 401 that has evolved from structure 301 (FIG. 3) through removal of material layers 202 selectively over material layers 201. Within structure 401 there is a continuous void 442 surrounding each of material layers 201. For an exemplary embodiments where material layers 202 are silicon and material layers 201 are SiGe, an isotropic silicon etch maybe practiced to from void 442. The silicon etch may be with an ALE process, for example. FIG. 5 further illustrates a cross-sectional side view of a structure 501 that evolved from structure 401 (FIG. 4) to further include a gate stack structure comprising a gate material 505 and a gate insulator 510. In the exemplary embodiment, gate insulator 510 separates gate material 505 from material layers 201.

Gate insulator 510 may have a relatively high dielectric constant (¿) and advantageously has a relative permittivity exceeding 9. In some high-K gate dielectric embodiments, gate insulator 510 is a metal oxide comprising oxygen and one or more metals, such as, but not limited to, aluminum, hafnium, zirconium, tantalum, or titanium. In other embodiments, gate insulator 510 is a ferroelectric. In still other embodiments, gate insulator 510 is primarily silica or an alternative dielectric material having a dielectric constant of 9, or below. Gate material 505 may be or include a metal such as but not limited to platinum, nickel, molybdenum, tungsten, palladium, gold, alloys thereof, or nitrides such as titanium nitride, tantalum nitride, tungsten silicon nitride, etc. In some embodiments, gate material 505 includes both a work function metal in contact with gate insulator 510 and a fill metal (not depicted) over the work function metal.

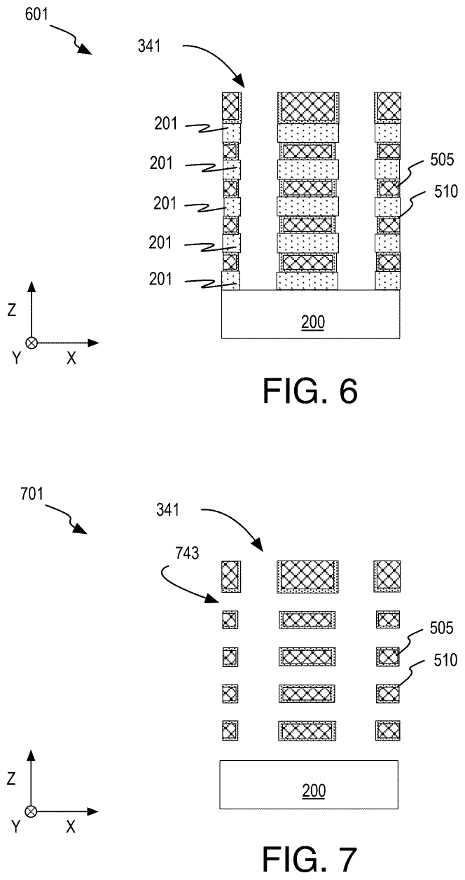

Methods 100 (FIG. 1) continue at block 106 where the second layers are removed from the material stack. For a selective etchant to gain access to the second layers, some of the sidewall spacer dielectric may be removed from around the features patterned at block 103, along within any other filler that may also have been deposited. FIG. 6 illustrates a cross-sectional view of a structure 601 that has evolved from structure 501 (FIG. 5) to again include open trenches 341. One or more solvent or etch processes may remove filler material 306 and sidewall spacer dielectric material 305 may be etched, for example with a silica etch that is selective over the composition of material layer 201 and selective over the composition of gate insulator 510, which becomes partially exposed with removal of sidewall spacer dielectric material 305.

As further illustrated in FIG. 7, material layers 201 have been removed from structure 601 (FIG. 6) to arrive at structure 701 (FIG. 7). As shown, following a selective etch of material layers 201, structure 701 consists essentially of a gate stack structure extending between trenches 341 and which has a vertical (e.g., z-dimension) stack of tunnels 743 passing through the length of the gate stack structure between trenches 341. Each of tunnels 743 is lined with gate insulator 510.

Methods 100 (FIG. 1) continue at block 108 where a 2D channel material layer is formed around surfaces of the gate stack structure. Depending on implementation, a channel material layer suitable for an n-type metal oxide semiconductor (NMOS) device or a p-type metal oxide semiconductor (PMOS) device may be formed. In exemplary embodiments, a 2D channel material layer comprising a metal chalcogenide is formed at block 108. In alternative embodiments, a graphene-based (or graphene family) material such as graphene, hexagonal boron nitride (hBN, white graphene), boron and nitrogen co-doped graphene (BCN), fluorographene, or graphene oxide is formed at block 108. In some other embodiments, a 2D oxide such as a mica or a bismuth strontium calcium copper oxide (BSCCO) including MoO₃ or WO3 is formed at block 108. In still other embodiments, a 2D oxide such as a layered copper oxide including TiO₂, MnO₂, V₂O₅, TaO₃, RuO₂, or the like, is formed at block 108. In other embodiments, a 2D oxide such as a perovskite-type including LaNb₂O₇, (Ca,Sr)₂Nb₃O₁₀, Bi₄Ti₃O₁₂, Ca₂Ta₂TiO₁₀, or the like, is formed at block 108. In still other embodiments, a 2D hydroxide including Ni(OH)₂ or Eu(OH)₂, or the like, is formed at block 108.

In exemplary metal chalcogenide embodiments, block 108 may comprise a molecular beam deposition process or a MOCVD process, for example. In some examples, the substrate is heated to over 400° C. (e.g., 450-1000° C.) in the presence of a chalcogen precursor gas, such as H₂S, H₂Se, or H₂Te. Since these exemplary precursors can also act as strong reducing agents, they may be combined or replaced with weaker reducing agents/stronger oxidizing agents. The deposition process may further include a vapor or liquid source of one or more metals, in addition to the chalcogen precursor. For example, a metal precursor may be the only source of metal incorporated into a 2D channel material layer. Although vapor/gas metalorganic sources are advantageous, liquid metalorganic precursors may also be used, for example with an MOCVD growth process that utilizes a bubbler.

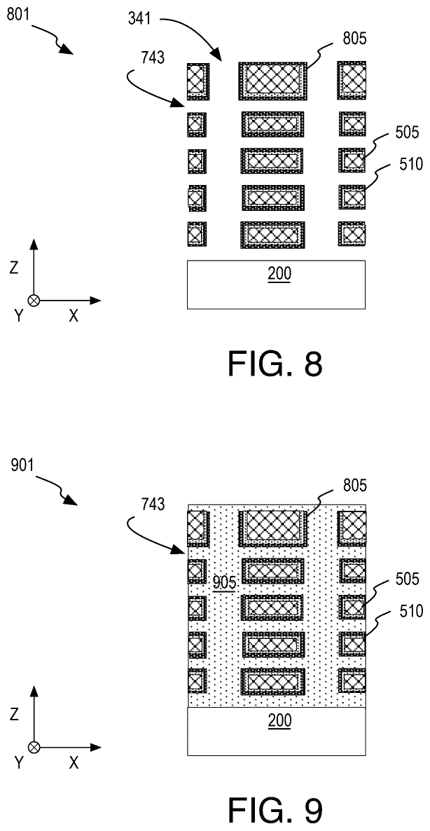

FIG. 8 illustrates structure 801, which includes a 2D channel material layer 805 that has been formed over structure 701 (FIG. 7). In this example where removing the material layers 201 from within the gate stack formed tunnels of a certain dimension, the 2D channel material layer 805 forms a liner or tube on the surface of gate insulator 510 through which the tunnel passes.

In some metal chalcogenide embodiments, channel material layer 805 is a dichalcogenide (MC₂). However, because other oxidation states are possible channel material layers 805 may be better characterized as MCₓ with x being between 0.2 and 4. For embodiments herein, chalcogens include at least one of sulfur, selenium or tellurium (oxygen is excluded), with S or Se being particularly advantageous. Channel material layer 805 may therefore be MSₓ, MSeₓ, or MTeₓ, for example. In some metal chalcogenide embodiments, channel material layer 805 has a thickness of no more than 2 nm.

In some exemplary embodiments, metal M is Cu, Zn, Zr, Re, Hf, Ir, Ru, Cd, Ni, Co, Pd, Pt, Ti, Cr, V, W Mo, Al, Sn, Ga, In, B, Ge, Si, P, As, or Sb. 2D channel material layer 805 may be predominantly one of these metals and one or more of the chalcogens. For example, the metal chalcogenide may be any of CuSₓ, CuSeₓ, CuTeₓ, ZnSₓ, ZnSeₓ, ZnTex ZrSₓ, ZrSeₓ, ZrTeₓ, ReSₓ, ReSeₓ, TeSeₓ RuSₓ, RuSeₓ, RuTeₓ IrSₓ, IrSeₓ, IrTeₓ, CdSₓ, CdSeₓ, CdTeₓ NiSₓ, NiSeₓ, NiTeₓ CoSₓ, CoSeₓ, CoTeₓ PdSₓ, PdSeₓ, PtSeₓ PtSₓ, PtSeₓ, PtTeₓ TiSₓ, TiSeₓ, TiTeₓ CrSₓ, CrSeₓ, CrTeₓ VSₓ, VSeₓ, VTeₓ, WSₓ, WSeₓ, WTeₓ MoSₓ, MoSeₓ, MoTeₓ, AlSₓ, AlSeₓ, AlTeₓ SnSₓ, SnSeₓ, SnTeₓ, GaSₓ, GaSeₓ, GaTeₓ InSₓ, InSeₓ, InTeₓ SbSₓ, SbSeₓ, SbTeₓ GeSₓ, GeSeₓ, GeTeₓ SiSₓ, SiSeₓ, or SiTex. Of these compounds, MoSₓ, MoSeₓ, MoTeₓ and WSₓ, WSeₓ, WTeₓ may be particularly advantageous for implementing a transistor. In further embodiments, the metal includes multiple metals as M1M2 or M1M2M3 alloys along with one or more of S, Se, or Te. For example, 2D channel material layer 805 may be InGaZnSex. In some advantageous embodiments, 2D channel material layer 805 is an n-type metal chalcogenide, such as MoS₂ or WS₂. In other advantageous embodiments, 2D channel material layer 805 is a p-type metal chalcogenide, such as MoSe₂ or WSe₂.

Returning to FIG. 1, methods 100 continue at block 109 where an insulator is deposited within any remaining space remaining around the gate stack that the 2D channel material does not occupy. For example, where removing the material layers 201 from within the gate stack formed tunnels of a certain dimension, a dielectric material may fill in any space within these tunnels that remains after cladding the gate stack structure with the 2D channel material. For example, an inorganic dielectric material, such as SiOCH or other low-k material, may be deposited with an ALD process. In structure 901, as further illustrated in FIG. 9, a dielectric material 905 has been deposited within tunnels 743. Dielectric material 905 may also backfill trenches 341. In exemplary embodiments where at least a portion of dielectric material 905 is to be retained in a final transistor structure, dielectric material 905 is a composition known to have a low relative permittivity (e.g., <3.5).

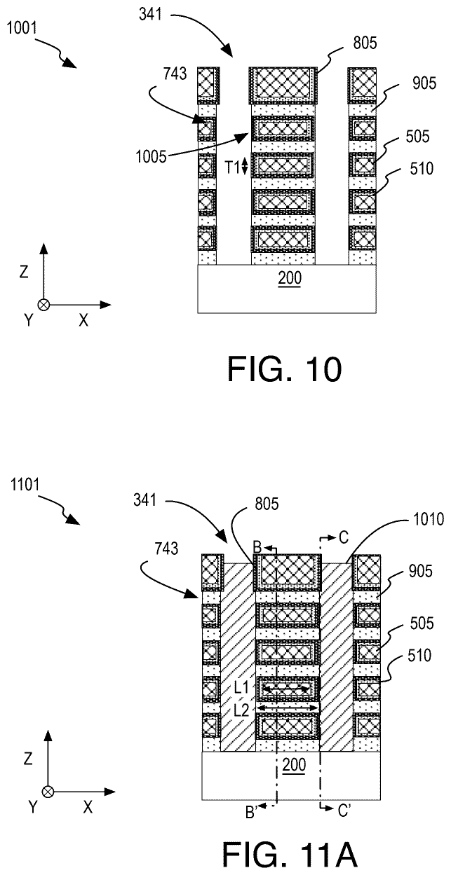

Returning to FIG. 1, methods 100 continue at block 110 where source and drain contacts/terminals are formed in contact with the 2D channel material. Source and drain contact formation may first comprise an etch process that reopens the trenches that may have been backfilled at block 109. Once open, these trenches expose opposite ends of the gate stack structure that is clad in the 2D channel material. In structure 1001, illustrated in FIG. 10, dielectric material 905 has been anisotropically etched to reopen trenches 341 while retaining dielectric material 905 within tunnels 743. Trenches 341 expose end cap surfaces 1005 of 2D channel material layer 805. Notably, end cap surfaces 1005 have a surface area that is a function of thickness T1 associated with material layer 201 that was previously replaced by the gate stack. End cap surfaces 1005 are essentially a “top” surface of 2D channel material layer 805, which encapsulates the gate stack structure. End cap surfaces 1005 may be arbitrarily larger than an edge surface of 2D channel material layer 805, which is no more than a few nanometers in thickness and would therefore result in significantly higher extrinsic resistance.

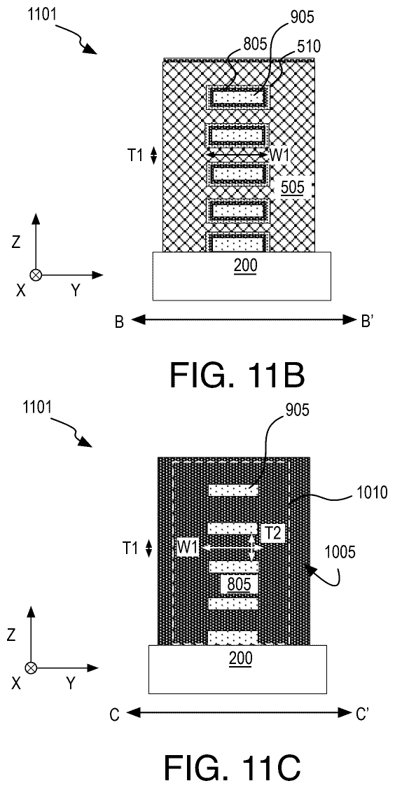

In FIG. 11A, transistor structure 1101 further includes source and drain contacts 1010, which have been formed within trenches 341 with an suitable deposition process (e.g., ALD, PVD, electroplating, etc.). Source and drain contacts 1010 are in direct contact with end cap surfaces 1005 of 2D channel material layer 805. As shown, gate material 505 has a longitudinal length L1 that is less than a length L2 between source and drain contacts 1010. Source and drain contacts 1010 may have any composition suitable for the composition of 2D channel material layer 805. In some embodiments, source and drain contacts 1010 comprise a metal and may further comprise nitrogen. In some embodiments where channel material layer 805 is a metal chalcogenide (e.g., WSₓ or WSex, MoSₓ or MoSeₓ), source and drain contacts 1010 may be antimony, ruthenium, titanium, for example. Source and drain contacts 1010 may also comprise a fill metal, such as, but not limited to, titanium, cobalt, tungsten, copper, or ruthenium. In one NMOS transistor example, source and drain contacts 1010 comprise Ti (e.g., Ti or TiN) in direct contact with channel material layer 805. In one PMOS transistor example, source and drain contacts 1010 comprise Ru (e.g., Ru or RUN) in direct contact with channel material layer 805.

The dot dashed lines denoting a plane B-B′ passing orthogonal to the plane illustrated in FIG. 11A and through a longitudinal length of the transistor channel is further illustrated in FIG. 11B. Likewise, the dot dashed lines denoting a plane C-C′ parallel to plane B-B′ but passing through an end cap portion of channel material layer 805 is further illustrated in FIG. 11C.

As shown in FIG. 11B, gate material 505 is a monolithic body surrounding a stack of tunnels lined with an annulus of gate insulator 510 which is further lined with an annular 2D channel material layer 805. 2D channel material layer 805 is therefore a nanotube structure surrounding dielectric material 905. As further illustrated, each nanotube of channel material has a lateral width W1 and is spaced apart from an adjacent nanotube by thickness T1.

As shown in FIG. 11C, 2D channel material layer 805 fully clads an end of the gate stack structure. The illustrated end cap surface 1005 of channel material layer 805 is available to be contacted by a source or drain contact 1010, which is illustrated in dashed line to avoid obscuring end cap surface 1005. Between each tunnel filled with dielectric material 905, end cap surface 1005 extend continuously over the intervening area defined by width W1 and thickness T2, which is larger than thickness T1 by approximately twice a thickness of the gate insulator (not depicted in FIG. 11C). In some examples where thickness T2 is at least 5 nm and width W1 is also at least 5 nm, the end cap surface 1005 between filaments of dielectric material 905 is in the range of 20-25 nm².

With three terminals fabricated, transistor structure 1101 is substantially complete. Returning to FIG. 1, methods 100 end at output 112 where any fabrication process known in the art may be practiced, for example to interconnect the transistor structure(s) fabricated in blocks 103-110 into integrated circuitry within a monolithic IC die. Further processing at output 112 may include forming interconnect features including metallization routings and vias, dicing, packaging, assembly, and so on. The resultant apparatus (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

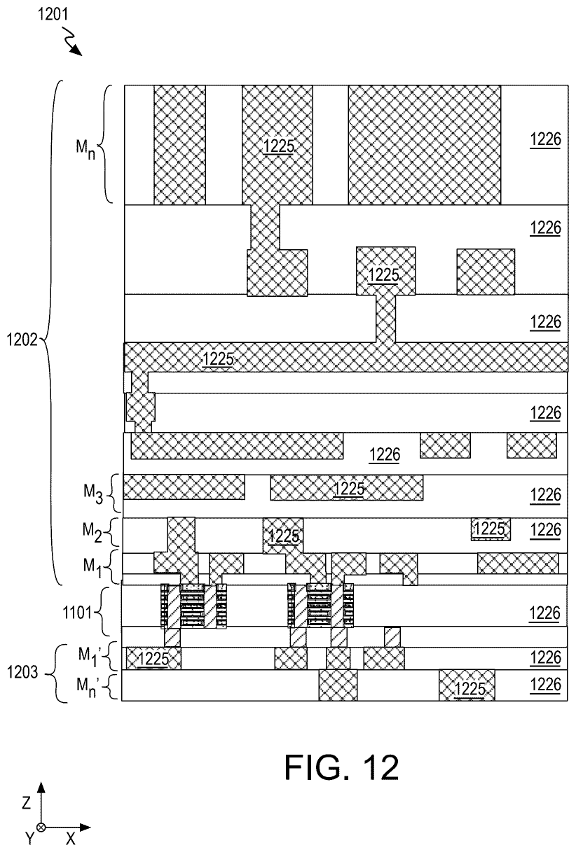

Transistor structures comprising a 2D material layer cladding a gate structure accordance with embodiments herein may be integrated into a wide variety of ICs and computing systems that include such ICs. FIG. 12 is a cross-sectional view of an IC structure 1201, in accordance with some embodiments further illustrating transistor structures 1101 as described above, for example. IC structure 1201 illustrates a portion of a monolithic IC die that includes FEOL interconnect metallization levels 1202 over and/or on a front side of a device layer that includes 2D transistor structure 1101 including 2D channel material cladding a gate stack structure, for example as described elsewhere herein.

Within IC structure 1201, front-side interconnect metallization levels 1202 include interconnect metallization 1225 electrically insulated by dielectric material 1226. In the exemplary embodiment illustrated, front-side interconnect metallization levels 1202 include metal-one (M₁), metal-two (M₂), metal-three (M₃) and metal-n (Mₙ) interconnect metallization levels. Interconnect metallization 1225 may be any metal(s) suitable for IC interconnection. Interconnect metallization 1225, may be, for example, an alloy of predominantly Cu, an alloy of predominantly W, an alloy of predominantly Ru, an alloy of predominantly Al, an alloy of predominantly Mo, etc. Dielectric material 1226 may be any dielectric material known to be suitable for electrical isolation of monolithic ICs. In some embodiments, dielectric material 1226 comprises silicon, and at least one of oxygen and nitrogen. Dielectric material 1226 may be SiO, SiN, or SiON, for example. Dielectric material 1226 may also be a low-K dielectric material (e.g., having a dielectric constant below that of SiO₂). Although metal-one is illustrated to have lines and vias of different heights, for example in accordance with some embodiments described above, any of the other metallization levels may have lines and vias of different heights.

IC structure 1201 further includes back-side interconnect metallization levels 1203. Within interconnect metallization levels 1203, interconnect metallization 1225 is again electrically insulated by dielectric material 1226. Back-side interconnect metallization levels 1203 may comprise any number of metallization levels over, or on, a back side of transistor structures 1101. In the illustrated example back-side metallization, metallization levels 1203 include a metallization level M₁′ nearest to transistor structures 1101 (e.g., opposite M₁) through an uppermost back-side metallization level Mₙ′.

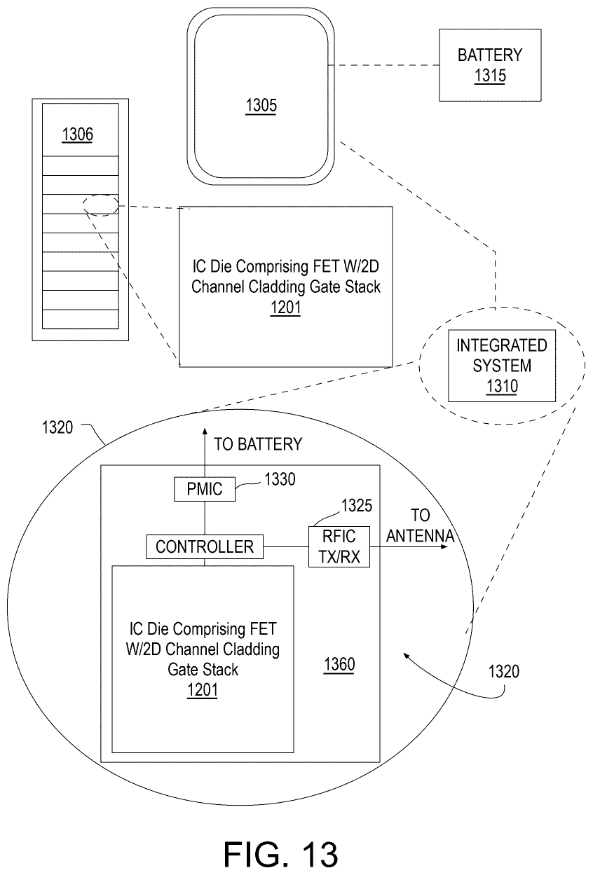

FIG. 13 illustrates a mobile computing platform 1305 and a data server machine 1306 employing a packaged IC die including 2D channel material cladding an exterior surface of a gate electrode structure, for example as described elsewhere herein. Server machine 1306 may be any commercial server, for example including any number of high-performance computing platforms disposed within a rack and networked together for electronic data processing, which in the exemplary embodiment includes a packaged IC die comprising IC structure 1201, for example as described elsewhere herein.

The mobile computing platform 1305 may be any portable device configured for each of electronic data display, electronic data processing, wireless electronic data transmission, or the like. For example, the mobile computing platform 1305 may be any of a tablet, a smart phone, laptop computer, etc., and may include a display screen (e.g., a capacitive, inductive, resistive, or optical touchscreen), an integrated system 1310, and a battery 1315.

As illustrated in the expanded view 1320, IC structure 1201 is further coupled to host component 1360. One or more of a power management integrated circuit (PMIC) 1330 or RF (wireless) integrated circuit (RFIC) 1325 including a wideband RF (wireless) transmitter and/or receiver may be further coupled to host component 1360. PMIC 1330 may perform battery power regulation, DC-to-DC conversion, etc., and so has an input coupled to battery 1315 and with an output providing a current supply to other functional modules. As further illustrated, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

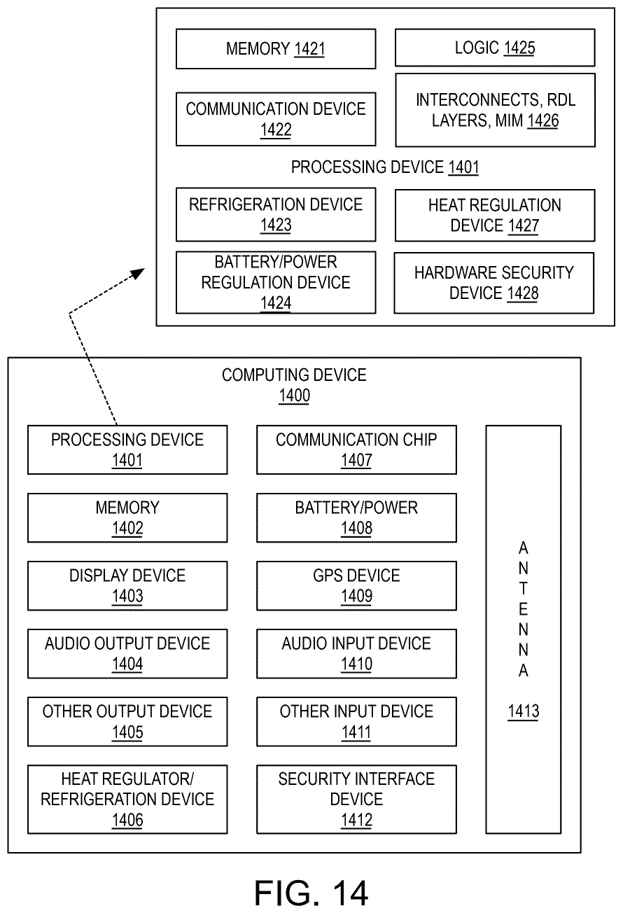

FIG. 14 is a block diagram of a cryogenically cooled computing device 1400 in accordance with some embodiments. For example, one or more components of computing device 1400 may include any of the devices or interconnect structures discussed elsewhere herein. A number of components are illustrated in FIG. 14 as included in computing device 1400, but any one or more of these components may be omitted or duplicated, as suitable for the application. In some embodiments, some or all of the components included in computing device 1400 may be attached to one or more printed circuit boards (e.g., a motherboard). In some embodiments, various ones of these components may be fabricated onto a single system-on-a-chip (SoC) die. Additionally, in various embodiments, computing device 1400 may not include one or more of the components illustrated in FIG. 14, but computing device 1400 may include interface circuitry for coupling to the one or more components. For example, computing device 1400 may not include a display device 1403, but may include display device interface circuitry (e.g., a connector and driver circuitry) to which display device 1403 may be coupled.

Computing device 1400 may include a processing device 1401 (e.g., one or more processing devices). As used herein, the term processing device or processor indicates a device that processes electronic data from registers and/or memory to transform that electronic data into other electronic data that may be stored in registers and/or memory. Processing device 1401 may include a memory 1421, a communication device 1422, a refrigeration/active cooling device 1423, a battery/power regulation device 1424, logic 1425, interconnects 1426 (i.e., optionally including redistribution layers (RDL) or metal-insulator-metal (MIM) devices), a heat regulation device 1427, and a hardware security device 1428.

Processing device 1401 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1401 may include a memory 1402, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1421 includes memory that shares a die with processing device 1401. This memory may be used as cache memory and may include embedded dynamic random-access memory (eDRAM) or spin transfer torque magnetic random-access memory (STT-M RAM).

Computing device 1400 may include a heat regulation/refrigeration device 1406. Heat regulation/refrigeration device 1406 may maintain processing device 1401 (and/or other components of computing device 1400) at a predetermined low temperature during operation. This predetermined low temperature may be any temperature discussed elsewhere herein.

In some embodiments, computing device 1400 may include a communication chip 1407 (e.g., one or more communication chips). For example, the communication chip 1407 may be configured for managing wireless communications for the transfer of data to and from computing device 1400. The term “wireless” and its derivatives may be used to describe circuits, devices, systems, methods, techniques, communications channels, etc., that may communicate data through the use of modulated electromagnetic radiation through a nonsolid medium.

Communication chip 1407 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1407 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1407 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1407 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1407 may operate in accordance with other wireless protocols in other embodiments. Computing device 1400 may include an antenna 1413 to facilitate wireless communications and/or to receive other wireless communications (such as AM or FM radio transmissions).

In some embodiments, communication chip 1407 may manage wired communications, such as electrical, optical, or any other suitable communication protocols (e.g., the Ethernet). As noted above, communication chip 1407 may include multiple communication chips. For instance, a first communication chip 1407 may be dedicated to shorter-range wireless communications such as Wi-Fi or Bluetooth, and a second communication chip 1407 may be dedicated to longer-range wireless communications such as GPS, EDGE, GPRS, CDMA, WiMAX, LTE, EV-DO, or others. In some embodiments, a first communication chip 1407 may be dedicated to wireless communications, and a second communication chip 1407 may be dedicated to wired communications.

Computing device 1400 may include battery/power circuitry 1408. Battery/power circuitry 1408 may include one or more energy storage devices (e.g., batteries or capacitors) and/or circuitry for coupling components of computing device 1400 to an energy source separate from computing device 1400 (e.g., AC line power).

Computing device 1400 may include a display device 1403 (or corresponding interface circuitry, as discussed above). Display device 1403 may include any visual indicators, such as a heads-up display, a computer monitor, a projector, a touchscreen display, a liquid crystal display (LCD), a light-emitting diode display, or a flat panel display, for example.

Computing device 1400 may include an audio output device 1404 (or corresponding interface circuitry, as discussed above). Audio output device 1404 may include any device that generates an audible indicator, such as speakers, headsets, or earbuds, for example.

Computing device 1400 may include an audio input device 1410 (or corresponding interface circuitry, as discussed above). Audio input device 1410 may include any device that generates a signal representative of a sound, such as microphones, microphone arrays, or digital instruments (e.g., instruments having a musical instrument digital interface (MIDI) output).

Computing device 1400 may include a global positioning system (GPS) device 1409 (or corresponding interface circuitry, as discussed above). GPS device 1409 may be in communication with a satellite-based system and may receive a location of computing device 1400, as known in the art.

Computing device 1400 may include another output device 1405 (or corresponding interface circuitry, as discussed above). Examples include an audio codec, a video codec, a printer, a wired or wireless transmitter for providing information to other devices, or an additional storage device.

Computing device 1400 may include another input device 1411 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1400 may include a security interface device 1412. Security interface device 1412 may include any device that provides security measures for computing device 1400 such as intrusion detection, biometric validation, security encode or decode, managing access lists, malware detection, or spyware detection. In some examples, security interface device 1412 comprises OTP ROM further including a via MIM fuse, for example as described elsewhere herein.

Computing device 1400, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described, but instead can be practiced with modification and alteration without departing from the scope of the appended claims. For example, the above embodiments may include specific combinations of features as further provided below.

In first examples, a transistor structure comprises a source contact and a drain contact, a gate electrode of a first length between opposite ends of the gate electrode that is less than a distance between the source contact and the drain contact, and a gate insulator of a second length wrapping around the first length of the gate electrode. The gate insulator is also between the opposite ends of the gate electrode and each of the source contact and the drain contact. The transistor structure comprises a channel material wrapping around the second length of the gate insulator. The channel material is also between each of the source contact and the drain contact and the gate insulator at opposite ends of the gate electrode.

In second examples, for any of the first examples the channel material comprises a metal and a chalcogen.

In third examples, for any of the second examples the metal comprises molybdenum or tungsten, and the chalcogen comprises sulfur or selenium.

In fourth examples, for any of the first through third examples the channel material is in direct contact with the source contact and the drain contact over an entirety of a cross-sectional area of the opposite ends of the gate electrode.

In fifth examples, for any of the first through fourth examples a vertical stack of tunnels through the gate electrode span the distance between the source contact and the drain contact, and the channel material is within the tunnels.

In sixth examples, for any of the fifth examples an annular layer of the channel material wraps around a filament of dielectric material within individual ones of the tunnels, and an annular layer of the gate insulator lines the tunnel and wraps around the annular layer of the channel material.

In seventh examples, for any of the sixth examples the annular layer of the channel material has a layer thickness of no more than 2 nm.

In eighth examples, for any of the seventh examples the channel material is continuous within a vertical space between individual ones of the tunnels, and wherein the channel material is in direct contact with the source contact or drain contact over an entirety of the vertical space between ones of the tunnels.

In ninth examples, for any of the eighth examples the vertical space between individual ones of the tunnels is at least 5 nm, and wherein individual ones of the tunnels has a lateral width of at least 5 nm.

In tenth examples for any of the ninth examples, between adjacent ones of the tunnels, the channel material is in direct contact with a cross-sectional area of the source contact or the drain contact that is at least 20 nm².

In eleventh examples, an integrated circuit (IC) die comprises a transistor structure, the transistor structure comprising a nanotube of channel material coupled between a source terminal and a drain terminal. The channel material comprises a metal and a chalcogen. The transistor structure comprises a gate stack wrapped around the nanotube, the gate stack comprising a gate insulator and a gate material. A first end of the nanotube is fully enclosed by a first portion of the channel material that is in direct contact with the source terminal. A second end of the nanotube is fully enclosed by a second portion of the channel material that is in direct contact with the drain terminal.

In twelfth examples, for any of the eleventh examples the transistor structure comprises a stack of the nanotubes, the gate stack wraps around each of the nanotubes, and the transistor structure further comprises a dielectric material filament surrounded by the gate stack and between an exterior of each of the nanotubes.

In thirteenth examples, for any of the twelfth examples the dielectric material between the nanotubes is in direct contact with both the source terminal and the drain terminal.

In fourteenth examples, for any of the twelfth through thirteenth examples the channel material is continuous between the first end of all of the nanotubes within the stack.

In fifteenth examples, for any of the fourteenth examples the channel material is continuous between the second end of all of the nanotubes within the stack.

In sixteenth examples, for any of the eleventh through fifteenth examples the first portion of the channel material has a surface area of at least 20 nm².

In seventeenth examples, a method comprises receiving a multilayer material stack comprising a plurality of first material layers interleaved with a plurality of second material layers. The method comprises replacing the first material layers with a gate stack comprising a gate electrode and gate insulator, the gate stack wrapping around the second material layers. The method comprises removing the second material layers, forming tunnels extending through a length of the gate stack. The method comprises forming a channel material over a surface of the gate stack, the channel material lining the tunnels, ns forming a source terminal and a drain terminal at opposite ends of the channel material lining the tunnels.

In eighteenth examples, for any of the seventeenth examples, the method further comprises patterning the multilayer material stack into a fin, and forming a sidewall spacer material adjacent to opposite ends of the fin.

In nineteenth examples, for any of the seventeenth through eighteenth examples forming the source terminal and a drain terminal comprises replacing the sidewall spacer material with a metal or metal nitride.

In twentieth examples, for any of the seventeenth through nineteenth examples the first and second material layers comprise silicon, the second material layers comprises a different amount of germanium than the first material layers, and the channel material comprises a metal and sulfur or selenium.

However, the above embodiments are not limited in this regard, and, in various implementations, the above embodiments may include the implementation of only a subset of such features, the implementation a different order of such features, the implementation of a different combination of such features, and/or the implementation of additional features than those features explicitly listed. The scope of the disclosure should, therefore, be determined with reference to the appended claims, along with the full scope of equivalents to which such claims are entitled.

What is claimed is:

1. A transistor structure, comprising:
a source contact and a drain contact;
a gate electrode of a first length between opposite ends of the gate electrode that is less than a distance between the source contact and the drain contact;
a gate insulator of a second length wrapping around the first length of the gate electrode, wherein the gate insulator is also between the opposite ends of the gate electrode and each of the source contact and the drain contact; and
a channel material wrapping around the second length of the gate insulator, wherein the channel material is also between each of the source contact and the drain contact and the gate insulator at opposite ends of the gate electrode.

2. The transistor structure of claim 1, wherein the channel material comprises a metal and a chalcogen.

3. The transistor structure of claim 2, wherein the metal comprises molybdenum or tungsten, and the chalcogen comprises sulfur or selenium.

4. The transistor structure of claim 1, wherein the channel material is in direct contact with the source contact and the drain contact over an entirety of a cross-sectional area of the opposite ends of the gate electrode.

5. The transistor structure of claim 1, wherein:
a vertical stack of tunnels through the gate electrode span the distance between the source contact and the drain contact;
and the channel material is within the tunnels.

6. The transistor structure of claim 5, wherein:
an annular layer of the channel material wraps around a filament of dielectric material within individual ones of the tunnels; and
an annular layer of the gate insulator lines the tunnels and wraps around the annular layer of the channel material.

7. The transistor structure of claim 6, wherein the annular layer of the channel material has a layer thickness of no more than 2 nm.

8. The transistor structure of claim 7, wherein the channel material is continuous within a vertical space between individual ones of the tunnels, and wherein the channel material is in direct contact with the source contact or drain contact over an entirety of the vertical space between ones of the tunnels.

9. The transistor structure of claim 8, wherein the vertical space between individual ones of the tunnels is at least 5 nm, and wherein individual ones of the tunnels has a lateral width of at least 5 nm.

10. The transistor structure of claim 9, wherein between adjacent ones of the tunnels, the channel material is in direct contact with a cross-sectional area of the source contact or the drain contact that is at least 20 nm².

11. An integrated circuit (IC) die comprising a transistor structure, the transistor structure comprising:
a nanotube of channel material coupled between a source terminal and a drain terminal, wherein the channel material comprises a metal and a chalcogen; and
a gate stack wrapped around the nanotube, the gate stack comprising a gate insulator and a gate material, wherein:
a first end of the nanotube is fully enclosed by a first portion of the channel material that is in direct contact with the source terminal; and
a second end of the nanotube is fully enclosed by a second portion of the channel material that is in direct contact with the drain terminal.

12. The IC die of claim 11, wherein:
the transistor structure comprises a stack of the nanotubes;
the gate stack wraps around each of the nanotubes; and
the transistor structure further comprises a dielectric material filament surrounded by the gate stack and between an exterior of each of the nanotubes.

13. The IC die of claim 12, wherein the dielectric material between the nanotubes is in direct contact with both the source terminal and the drain terminal.

14. The IC die of claim 12, wherein the channel material is continuous between the first end of all of the nanotubes within the stack.

15. The IC die of claim 14, wherein the channel material is continuous between the second end of all of the nanotubes within the stack.

16. The IC die of claim 11, wherein the first portion of the channel material has a surface area of at least 20 nm².

17. A method, comprising:
receiving a multilayer material stack comprising a plurality of first material layers interleaved with a plurality of second material layers;
replacing the first material layers with a gate stack comprising a gate electrode and gate insulator, the gate stack wrapping around the second material layers;
removing the second material layers, forming tunnels extending through a length of the gate stack;
forming a channel material over a surface of the gate stack, the channel material lining the tunnels; and
forming a source terminal and a drain terminal at opposite ends of the channel material lining the tunnels.

18. The method of claim 17, further comprising:
patterning the multilayer material stack into a fin; and
forming a sidewall spacer material adjacent to opposite ends of the fin.

19. The method of claim 18, wherein forming the source terminal and a drain terminal comprises replacing the sidewall spacer material with a metal or metal nitride.

20. The method of claim 17, wherein:
the first and second material layers comprise silicon;
the second material layers comprises a different amount of germanium than the first material layers; and
the channel material comprises a metal and sulfur or selenium.
